(19) United States
(12) Patent Application Publication
(10) Pub. No.: US 2008/0242253 A1
(43) Pub. Date: Oct. 2, 2008

(54) Frequency converter and radio receiver using the same

(75) Inventor: Takafumi Yamaji, Yokohama-shi (JP)

Correspondence Address: NIXON & VANDERHYE, PC, 901 NORTH GLEBE ROAD, 11TH FLOOR, ARLINGTON, VA, 22203, US

(73) Assignee: KABUSHIKI KAISHA TOSHIBA, Tokyo (JP)

(21) Appl. No.: 12/076,659

(22) Filed: Mar. 20, 2008

(30) Foreign Application Priority Data
Mar. 30, 2007 (JP) 2007-094906

(51) Int. Cl. H04B 1/16; H03B 19/00

(52) U.S. Cl. 455/318; 327/113

(57) ABSTRACT

According to an embodiment of the invention, there is provided a frequency converter including: an input circuit converting a voltage signal to a current signal; a load circuit supplying a constant current to an input circuit; a first switch circuit configured to output a current signal from the first output terminal in accordance with a switching made in accordance with a first oscillation signal; a second switch circuit configured to output the current signal from the second output terminal in accordance with a switching made in accordance with a second oscillation signal being 180 degrees out of phase with the first oscillation signal; a control circuit generating a control current based on a predetermined reference voltage and an average voltage of the voltages at the first and second output terminals and adding the control current to the current signal of the input circuit.

### CROSS-REFERENCE TO RELATED APPLICATIONS

This application is based on and claims the benefit of priority from the prior Japanese Patent Application No. 2007-094906, filed on Mar. 30, 2007; the entire contents of which are incorporated herein by reference.

### TECHNICAL FIELD

The present invention relates to a frequency converter and a radio receiver using the same.

### BACKGROUND

A frequency converter is widely used in a radio receiver or the like. The frequency converter includes an input circuit that converts an input voltage signal to a current signal and a switch circuit that distributes the current signal to two output terminals in accordance with a switch-drive oscillation signal, so that an output signal is differentially outputted from the two output terminals. The frequency converter may produce smaller noise and to provide a larger conversion gain.

It is disclosed by, for example, Japanese patent No. 3665714 that an active load uses for increasing the conversion gain of the frequency converter.

However, the frequency converter disclosed in the Japanese patent No. 3665714 can increase the conversion gain, but in cases, for example, when down-converting a radio signal, especially that received by a radio receiver, the frequency converter is greatly influenced by the flicker noise (1/f noise) originating from transistors that serve as the active load.

As described above, although the frequency converter disclosed in the Japanese patent No. 3665714 can increase the conversion gain, the frequency converter is highly susceptible to the flicker noise.

### SUMMARY

According to an embodiment of the present invention, there is provided a frequency converter including: an input circuit converting a voltage signal to a current signal; a first and second output terminals both outputting a differential output signal based on the converted voltage signal; a load circuit supplying a constant current to an input circuit; a first switch circuit provided between a load circuit and the input circuit and configured to output the current signal from the first output terminal in accordance with a switching that is made in accordance with a first oscillation signal; a second switch circuit provided between the load circuit and the input circuit and configured to output the current signal from the second output terminal in accordance with a switching that is made in accordance with a second oscillation signal being 180 degrees out of phase with the first oscillation signal; a control circuit generating a control current based on a predetermined reference voltage and an average voltage of the voltages at the first and second output terminals and adding the control current to the current signal of the input circuit.

### BRIEF DESCRIPTION OF THE DRAWINGS

In the accompanying drawings:

FIG. 1 is an exemplary block diagram showing the configuration of a frequency converter according to a first embodiment of the invention;

FIG. 2 is an exemplary block diagram showing the configuration of a control circuit according to the first embodiment;

FIG. 3 is an exemplary block diagram showing the configuration of a frequency converter according to a second embodiment of the invention;

FIG. 4 is an exemplary block diagram showing the configuration of a control circuit according to the second embodiment;

FIG. 5 is an exemplary block diagram showing the configuration of a frequency converter according to a third embodiment of the invention;

FIG. 6 is an exemplary block diagram showing the configuration of a control circuit according to the third embodiment;

FIG. 7 is an exemplary block diagram showing the configuration of a frequency converter according to a fourth embodiment of the invention; and

FIG. 8 is an exemplary block diagram showing the configuration of a radio receiver according to a fifth embodiment of the invention.

### DESCRIPTION OF THE EMBODIMENTS

Hereinafter, embodiments of the invention will be described.

### First Embodiment

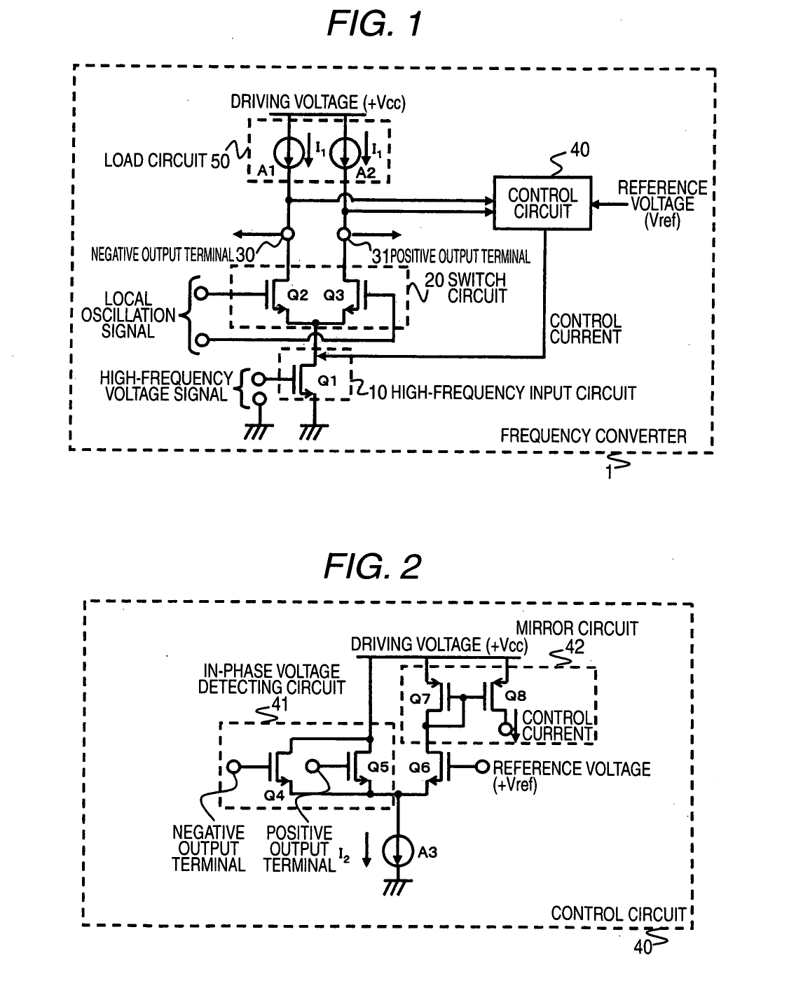

FIG. 1 is a block diagram showing the configuration of a frequency converter according to a first embodiment of the invention.

A frequency converter 1 of the first embodiment includes an n-channel MOSFET transistor Q1 in which a high-frequency voltage signal is inputted to a gate and a source is connected to the ground; n-channel MOSFET transistors Q2 and Q3 in which a local oscillation signal is differentially inputted to respective gates, respective sources are connected to the drain of the transistor Q1, and respective drains are connected to a negative output terminal 30 or a positive output terminal 31; a constant current source A1 that supplies a constant current I1 to the drain of the transistor Q2; a constant current source A2 that supplies a constant current I2 to the drain of the transistor Q3; and a control circuit 40 that generates a control current on the basis of a difference between a predetermined reference voltage Vref and the common mode voltage supplied from the negative output terminal 30 and the positive output terminal 31 and supplies the control current to the drain of the transistor Q1.

The transistor Q1 serves as a high-frequency input circuit 10 that converts the high-frequency voltage signal as an input signal to the frequency converter 1 to a high-frequency current signal. The transistors Q2 and Q3 serve as a switch circuit 20 that distributes the high-frequency current signal to the negative output terminal 30 or the positive output terminal 31. The constant current sources A1 and A2 serve as a load circuit 50 that supplies a bias current to the high-frequency input circuit 10. The local oscillation signal inputted to the gate of the transistor Q2 and the local oscillation signal inputted to the gate of the transistor Q3 are 180 degrees out of phase with each other. Thus, the transistors Q2 and Q3 operate in a differential manner.

FIG. 2 is a block diagram showing the configuration of the control circuit 40 according to the first embodiment of the invention.

The control circuit 40 includes an n-channel MOSFET transistor Q4 in which a gate is connected to the negative output terminal 30 and a power supply voltage Vcc is supplied to a drain; an n-channel MOSFET transistor Q5 in which a gate is connected to the positive output terminal 31 and the power supply voltage Vcc is supplied to a drain; an n-channel MOSFET transistor Q6 in which the reference voltage Vref is supplied to a gate; a constant current source A3 that supplies a constant current I2 from the sources of the transistors Q4, Q5, and Q6 to the ground; a p-channel MOSFET transistor Q7 in which a gate and a drain are connected to the drain of the transistor Q6 and the power supply voltage Vcc is supplied to a source; and a p-channel MOSFET transistor Q8 in which a gate is connected to the gate of the transistor Q7 and to the drain of the transistor Q6 and the power supply voltage Vcc is supplied to a source.

The transistors Q4 and Q5 serve as a common mode voltage detecting circuit 41 that detects a common mode voltage of the voltages at the negative output terminal 30 and the positive output terminal 31 that operate in a differential manner. Here, the common mode voltage can be obtained by calculating an average voltage of the voltages at the negative output terminal 30 and the positive output terminal 31. In addition, the transistors Q7 and Q8 serve as a mirror circuit 42. Therefore, the drain current of the transistor Q7, the drain current of the transistor Q6, and the drain current (the control current) of the transistor Q8 have the same current value.

Next, the operation of the frequency converter 1 of the first embodiment will be described.

First, the high-frequency voltage signal as the input signal to the frequency converter 1 is inputted to the gate of the transistor Q1. Since the gate of the transistor Q1 is supplied with the high-frequency voltage signal, the bias current flowing between the source and the drain of the transistor Q1 and supplied from the load circuit 50 fluctuates with the high-frequency voltage signal that is inputted to the gate of the transistor Q1. The bias current that fluctuates with the high-frequency voltage signal is referred to as the high-frequency current signal.

Next, the high-frequency current signal is outputted from the negative output terminal 30 or the positive output terminal 31 to which is connected the drains of the transistors Q2 and Q3 that serve as the switch circuit 20. The local oscillation signal is differentially inputted to the gates of the transistors Q2 and Q3. For this reason, when one of the transistors Q2 and Q3 is turned ON, the other transistor is turned OFF. That is, the transistors Q2 and Q3 are alternately turned ON and OFF in accordance with the local oscillation signal in a repeated manner. The high-frequency current signal is outputted from the negative output terminal 30 or the positive output terminal 31 via any one of the transistors Q2 and Q3.

In this case, the high-frequency current signal is distributed to the negative output terminal 30 and the positive output terminal 31 in accordance with a frequency of the local oscillation signal applied to the gates of the transistors Q2 and Q3. For this reason, from the negative output terminal 30 (or the positive output terminal 31) is outputted a current (output signal) having a frequency different from the frequency of the high-frequency current signal (i.e., different from the frequency of the input high-frequency voltage signal).

Next, the operation of the control circuit 40 of the first embodiment will be described.

First, the voltages at the negative output terminal 30 and the positive output terminal 31 of the frequency converter 1 are inputted to the common mode voltage detecting circuit 41 of the control circuit 40. That is, the voltage at the negative output terminal 30 is applied to the gate of the transistor Q4 and thus drives the transistor Q4. Meanwhile, the voltage at the positive output terminal 31 is applied to the gate of the transistor Q5 and thus drives the transistor Q5. In addition, the reference voltage Vref is applied to the gate of the transistor Q6 disposed in parallel to the transistors Q4 and Q5 and thus drives the transistor Q6.

Here, the sum of the drain currents of the transistors Q4, Q5, and Q6 is fixed at the current value I2 of the constant current source A3. For this reason, the drain currents of the transistors Q4, Q5, and Q6 are determined by a magnitude relation between the respective gate voltages. In addition, the gate voltage of the transistor Q6 is fixed at the reference voltage Vref. Therefore, the drain current of the transistor Q6 is determined by an average voltage of the gate voltage (the voltage at the negative output terminal 30) of the transistor Q4 and the gate voltage (the voltage at the positive output terminal 31) of the transistor Q5.

Since the negative output terminal 30 and the positive output terminal 31 are configured to output a differential output signal, the average voltage of the voltages at the negative output terminal 30 and the positive output terminal 31 is the common mode voltage of the differential output signal. When the common mode voltage of the differential output signal of the frequency converter 1 increases, the drain currents of the transistors Q4 and Q5 increase and the drain current of the transistor Q6 decreases. On the other hand, when the common mode voltage of the differential output signal of the frequency converter 1 decreases, the drain currents of the transistors Q4 and Q5 decrease and the drain current of the transistor Q6 increases.

The drain current of the transistor Q6 is the same as the drain current of the transistor Q7 that is serially connected to the transistor Q6. Since the gates of the transistors Q7 and Q8 are connected to each other and thus have the same voltage, the drain current of the transistor Q7 is the same as the drain current of the transistor Q8. The drain current of the transistor Q8 serves as the control current and is outputted from the control circuit 40.

The control current outputted from the control circuit 40 flows to the drain of the transistor Q1 that serves as the high-frequency input circuit 10. The gate voltage of the transistor Q1 is the high-frequency voltage signal and the drain current thereof is the high-frequency current signal. Therefore, the control current outputted by the control circuit 40 is added to the high-frequency current signal.

The control current added to the high-frequency current signal is outputted from the negative output terminal 30 or the positive output terminal 31 of the transistors Q2 and Q3 that serve as the switch circuit 20, in a manner similar to the high-frequency current signal. For this reason, the amount of the current outputted from the negative output terminal 30 or the positive output terminal 31 is increased by an amount corresponding to the control current added to the high-frequency current signal, thereby increasing the voltage.

For this reason, when the common mode voltage (the average voltage of the voltages at the negative output terminal 30 and the positive output terminal 31) of the differential output signal of the frequency converter 1 decreases, the control current outputted by the control circuit 40 increases, thus increasing the voltage at the negative output terminal 30 or the positive output terminal 31. Meanwhile, when the common mode voltage increases, the control current outputted by the control circuit 40 decreases, thus decreasing the voltage at the negative output terminal 30 or the positive output terminal 31. That is, the voltages at the negative output terminal 30 and the positive output terminal 31 are coupled to each other in a negative feedback manner. For this reason, it is possible to prevent that the voltage at the negative output terminal 30 or the positive output terminal 31 is abnormally increased to be close to the power supply voltage Vcc. Similarly, it is also possible to prevent that the voltage is abnormally decreased to be close to the ground voltage.

Due to a configuration in which a constant current source is used as a load circuit of a frequency converter, electric charges are likely to accumulate in the negative output terminal 30 or the positive output terminal 31, when a transistor serving as a switch circuit is in the OFF state. Accordingly, an abnormal in the voltage at the terminal increases. However, according to the frequency converter 1 of the first embodiment, the operation of the control circuit 40 can prevent an abnormal change in the voltage at the negative output terminal 30 or the positive output terminal 31.

Since the constant current sources A1 and A2 that are used as the load circuit 50 have very large resistance values, it is possible to prevent the high-frequency current signal (i.e., output signal) having passed through the switch circuit 20 from leaking to a power supply line via the load circuit 50. As a result, it is possible to suppress attenuation of the output signal and thus to increase the conversion gain of the frequency converter 1.

Hereinafter, the reason why the frequency converter 1 of the first embodiment can diminish the effect of the flicker noise will be described.

The power spectrum (or a square of the noise voltage) of the flicker noise is proportional to the current flowing between a drain and a source of a transistor and is inversely proportional to the frequency. Therefore, in order to diminish the effect of the flicker noise, the current flowing to a transistor that is operable at a low frequency may decrease.

For example, in the case in which the high-frequency voltage signal as the input signal to the frequency converter 1 is down-converted and outputted therefrom, the frequency of the high-frequency voltage signal for driving the transistor Q1 is set so as to be substantially equal to that of the local oscillation signal for driving the transistors Q2 and Q3. Then, the high-frequency current signal of the transistor Q1 is distributed to the negative output terminal 30 or the positive output terminal 31 in accordance with the local oscillation signal having a frequency substantially equal to that of the high-frequency current signal. The high-frequency current signal is then down-converted and outputted from the negative output terminal 30 or the positive output terminal 31.

Among the transistors included in the frequency converter 1 of the first embodiment, the transistors (not shown) that serve as the constant current sources A1 and A2 operate at a substantially zero frequency, thus producing a large flicker noise. In addition, the transistors Q4 to Q8 that serve as the control circuit 40 are driven by the common mode voltage of the differential output signal of the frequency converter 1 and therefore operate at a substantially zero frequency, thus producing a large flicker noise. On the other hand, the transistor Q1 that is driven by the high-frequency voltage signal and the transistors Q2 and Q3 that are driven by the local oscillation signal operate at a relatively high frequency, thus producing a small flicker noise.

Similarly, in the case in which the high-frequency voltage signal as the input signal to the frequency converter 1 is up-converted and outputted therefrom, the transistors Q1 to Q3 produce a small flicker noise while the transistors that serve as the constant current sources A1 and A2 and the control circuit 40 produce a large flicker noise.

Hereinafter, the reason why it is possible to diminish the effect of the flicker noise produced by the transistors that serve as the constant current sources A1 and A2 will be described. In the frequency converter of the first embodiment, the drain current of the transistor Q1 that is driven by the high-frequency voltage signal is supplied from the constant current sources A1 and A2 and the control circuit 40. For this reason, compared to the case in which the drain current of the transistor Q1 is supplied only from the constant current sources A1 and A2, the current flowing to the transistors that serve as the constant current sources becomes smaller, thus decreasing the flicker noise.

Next, the reason why it is possible to diminish the effect of the flicker noise produced by the transistors Q4 to Q8 that serve as the control circuit 40 will be described. First, the flicker noise produced by the transistors Q4 to Q8 and the transistors (not shown) that serve as the constant current source A3 is a current component and has an influence on the drain currents of these transistors. That is, in the drain current (control current) of the transistor Q8, a current component that originates from the flicker noise produced by the transistors that serve as the control circuit 40 is included.

Here, since the control current is added to the high-frequency current signal, the current component included in the control current that originates from the flicker noise is added to the high-frequency current signal. The current component originating from the flicker noise is outputted as a part of the output signal from the negative output terminal 30 and the positive output terminal 31 via the switch circuit 20 in a manner similar to the high-frequency current signal.

In the case in which the high-frequency voltage signal as the input signal to the frequency converter 1 is down-converted and outputted therefrom, a change rate of the local oscillation signal, which is determined by the frequency rate of the local oscillation signal, is much higher than the change rate of the current component that originates from the flicker noise.

For this reason, the flicker noise that appears at the negative output terminal 30 or the positive output terminal 31 is up-converted by the transistors Q2 and Q3 that are turned ON and OFF in a repeated manner. That is, the current component that originates from the flicker noise and appears at the negative output terminal 30 or the positive output terminal 31 is mainly composed of frequency components that are close to the operating frequency of the local oscillation signal.

On the other hand, the high-frequency current signal that is the signal component is down-converted by the transistors Q2 and Q3 that are turned ON and OFF in accordance with the operating frequency of the local oscillation signal in a repeated manner. That is, the current component that originates from the high-frequency current signal and appears at the negative output terminal 30 or the positive output terminal 31 is mainly composed of frequency components that are lower than the operating frequency of the local oscillation signal.

Therefore, in the output signal outputted from the negative output terminal 30 or the positive output terminal 31 of the frequency converter 1, not only the current component that originates from the high-frequency current signal but also the current component that originates from the flicker noise produced by the transistors that serve as the control circuit 40 are included. However, since the frequency components of the current component that originates from the high-frequency current signal are different from the frequency components of the current component that originates from the flicker noise, it is possible to filter out only the current component that originates from the flicker noise by means of a filter or the like in a simple manner. Meanwhile, the current component that originates from the flicker noise may also be supplied to the negative output terminal 30 or the positive output terminal 31 without being up-converted. However, such a flicker noise-originated current component is supplied to the negative output terminal 30 or the positive output terminal 31 as the common mode current and thus has little influence on the differential output signal.

For example, even when the frequency converter 1 of the present embodiment is used in a radio receiver for down-conversion of an input radio signal, since the frequency converter can diminish the effect of the flicker noise, the flicker noise has little influence on the signal reception characteristics of the radio receiver.

In the case in which the input signal to the frequency converter 1 is up-converted and outputted therefrom, since the output signal is converted to a high-frequency signal, the flicker noise has little influence on the output signal since the flicker noise is inversely proportional to the operating frequency of the transistor

In this way, according to the frequency converter 1 of the first embodiment, the control current generated on the basis of the difference between the predetermined reference voltage and the output voltage (common mode voltage) of the frequency converter 1 is added to the high-frequency current signal that is converted by the high-frequency input circuit 10. Accordingly, it is possible to increase the conversion gain and to diminish the effect of the flicker noise.

In the frequency converter 1 of the first embodiment, the transistors Q1 to Q8 are described and illustrated as being configured as an n-channel MOSFET or a p-channel MOSFET, but the invention is not limited to this.

For example, the transistors Q1 to Q8 may be configured as an npn-type bipolar transistor or a pnp-type bipolar transistor. Besides, in addition to the types described and illustrated above, the transistors Q1 to Q8 may also be configured as various types of transistors such as HEMT (high electron mobility transistor) or hetero junction bipolar transistors.

### Second Embodiment

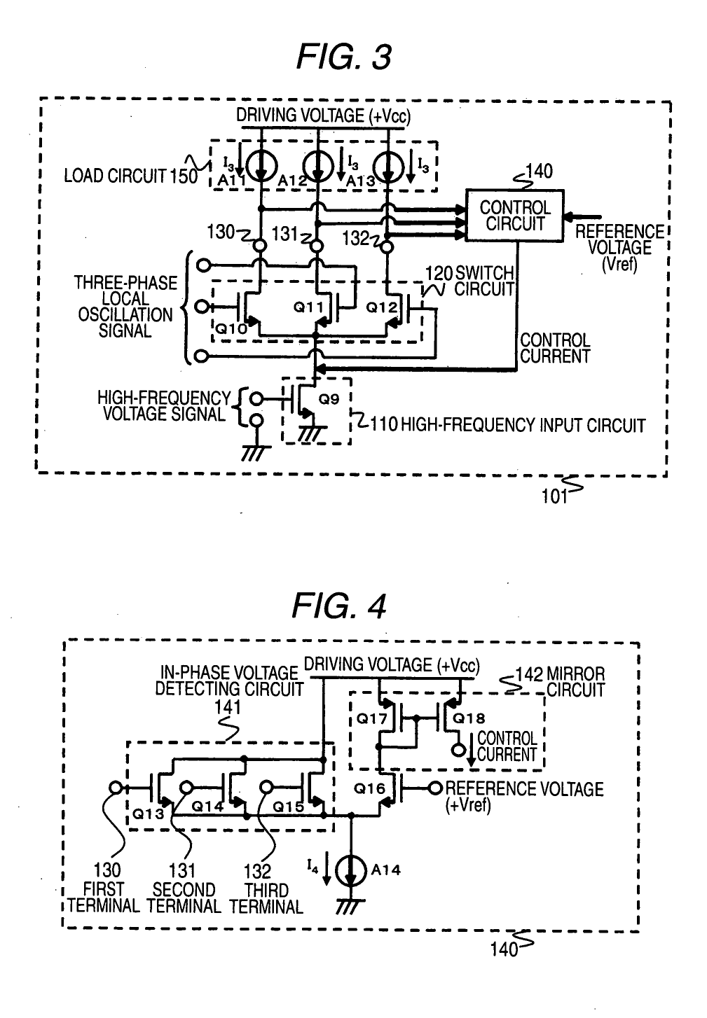

FIG. 3 is a block diagram showing the configuration of a frequency converter according to a second embodiment of the invention.

A frequency converter 101 of the second embodiment includes an n-channel MOSFET transistor Q9 in which a high-frequency voltage signal is inputted to a gate and a source is connected to the ground; n-channel MOSFET transistors Q10 to Q12 in which a three-phase local oscillation signal is inputted to respective gates, respective sources are connected to the drain of the transistor Q9, and respective drains are connected to any one of first to third terminals 130 to 132; a constant current source All that supplies a constant current I3 to the drain of the transistor Q10; a constant current source A12 that supplies a constant current I3 to the drain of the transistor Q11; a constant current source A13 that supplies a constant current I3 to the drain of the transistor Q12; and a control circuit 140 that generates a control current on the basis of a difference between a predetermined reference voltage Vref and the common mode voltage supplied from the first to third terminals 130 to 132 and supplies the control current to the drain of the transistor Q9.

The transistor Q9 serves as a high-frequency input circuit 110 that converts the high-frequency voltage signal as an input signal to the frequency converter 101 to a high-frequency current signal. The transistors Q10 to Q12 serve as a switch circuit 120 that distributes the high-frequency current signal to any one of the first to third terminals 130 to 132. The constant current sources A11 to A13 serve as a load circuit 150 that supplies a bias current to the high-frequency input circuit 110. The local oscillation signal inputted to the gate of the transistor Q10 and the local oscillation signal inputted to the gate of the transistor Q11 are 120 degrees out of phase with each other. In addition, the local oscillation signal inputted to the gate of the transistor Q12 is 120 degrees out of phase with the respective local oscillation signals inputted to the transistors Q10 and Q11.

FIG. 4 is a block diagram showing the configuration of the control circuit 140 in accordance with the second embodiment of the invention.

The control circuit 140 includes an n-channel MOSFET transistor Q13 in which a gate is connected to the first terminal 130 and a power supply voltage Vcc is supplied to a drain; an n-channel MOSFET transistor Q14 in which a gate is connected to the second terminal 131 and the power supply voltage Vcc is supplied to a drain; an n-channel MOSFET transistor Q15 in which a gate is connected to the third terminal 132 and the power supply voltage Vcc is supplied to a drain; an n-channel MOSFET transistor Q16 in which the reference voltage Vref is supplied to a gate; a constant current source A14 that supplies a constant current I4 from the sources of the transistors Q13 to Q16 to the ground; a p-channel MOSFET transistor Q17 in which a gate and a drain are connected to the drain of the transistor Q16 and the power supply voltage Vcc is supplied to a source; and a p-channel MOSFET transistor Q18 in which a gate is connected to the gate of the transistor Q17 and to the drain of the transistor Q16 and the power supply voltage Vcc is supplied to a source.

The transistors Q13 to Q15 serve as a common mode voltage detecting circuit 141 that detects a common mode voltage of the voltages at the first to third terminals 130 to 132 that output the three-phase output signal. Here, the common mode voltage can be obtained by calculating the sum of the voltages at the first to third terminals 130 to 132. In addition, the transistors Q17 and Q18 serve as a mirror circuit 142. Therefore, the drain current of the transistor Q17, the drain current of the transistor Q16, and the drain current (the control current) of the transistor Q18 have the same current value.

Next, the operation of the frequency converter 101 of the second embodiment will be described.

First, the high-frequency voltage signal as the input signal to the frequency converter 101 is inputted to the gate of the transistor Q9. Since the gate of the transistor Q9 is supplied with the high-frequency voltage signal, the bias current flowing between the source and the drain of the transistor Q9 and supplied from the load circuit 150 fluctuates with the high-frequency voltage signal inputted to the gate of the transistor Q9. The bias current that fluctuates with the high-frequency voltage signal is referred to as the high-frequency current signal.

Next, the high-frequency current signal is outputted from any one of the first to third terminals 130 to 132 via the transistors Q10 to Q12 that serve as the switch circuit 120. The three-phase local oscillation signal is inputted to the gates of the transistors Q10 to Q12. For this reason, when any one of the transistors Q10 to Q12 is turned ON, the other two transistors are turned OFF. That is, the transistors Q10 to Q12 are turned ON and OFF in a repeated manner. The high-frequency current signal is outputted from any one of the first to third terminals 130 to 132 via any one of the transistors Q10 to Q12.

In this case, the high-frequency current signal is distributed to any one of the first to third terminals 130 to 132 in accordance with a frequency of the local oscillation signal. For this reason, the first to third terminals 130 to 132 are supplied with a current (output signal) having a frequency different from the frequency of the high-frequency current signal (i.e., different from the frequency of the input high-frequency voltage signal).

Next, the operation of the control circuit 140 of the second embodiment will be described.

First, the voltages at the first to third terminals 130 to 132 of the frequency converter 101 are inputted to the common mode voltage detecting circuit 141 of the control circuit 140. That is, the voltage at the first terminal 130 drives the transistor Q13; the voltage at the second terminal 131 drives the transistor Q14; and the voltage at the third terminal 132 drives the transistor Q15. In addition, the reference voltage Vref drives the transistor Q16 disposed in parallel to the transistors Q13 to Q15.

Here, the sum of the drain currents of the transistors Q13 to Q16 is fixed at the current value I4 of the constant current source A14. For this reason, the drain currents of the transistors Q13 to Q16 are determined by a magnitude relation between the respective gate voltages. In addition, the gate voltage of the transistor Q16 is fixed at the reference voltage Vref. Therefore, the drain current of the transistor Q16 is determined by an average voltage of the gate voltage (the voltage at the first terminal 130) of the transistor Q13, the gate voltage (the voltage at the second terminal 131) of the transistor Q14, and the gate voltage (the voltage at the third terminal 132) of the transistor Q15.

Since the first to third terminals 130 to 132 are configured to output a three-phase output signal, the summed voltage of the voltages at the first to third terminals 130 to 132 is the common mode voltage of the three-phase output signal. When the common mode voltage of the three-phase output signal of the frequency converter 101 increases, the drain currents of the transistors Q13 to Q15 increase and the drain current of the transistor Q16 decreases. On the other hand, when the common mode voltage of the three-phase output signal of the frequency converter 101 decreases, the drain currents of the transistors Q13 to Q15 decrease and the drain current of the transistor Q16 increases.

The drain current of the transistor Q16 is the same as the drain current of the transistor Q17 that is serially connected to the transistor Q16. Since the gates of the transistors Q17 and Q18 are connected to each other and thus have the same voltage, the drain current of the transistor Q17 is the same as the drain current of the transistor Q18. The drain current of the transistor Q18 serves as the control current and is outputted from the control circuit 140.

The control current outputted from the control circuit 140 flows to the drain of the transistor Q9 that serves as the high-frequency input circuit 110. The gate voltage of the transistor Q9 is the high-frequency voltage signal and the drain current thereof is the high-frequency current signal. Therefore, the control current outputted by the control circuit 140 is added to the high-frequency current signal.

The control current added to the high-frequency current signal is outputted from any one of the first to third terminals 130 to 132 via the transistors Q10 to Q12 that serve as the switch circuit 120, in a manner similar to the high-frequency current signal. For this reason, the amount of the current outputted from any one of the first to third terminals 130 to 132 is increased by an amount corresponding to the control current added to the high-frequency current signal, thereby increasing the voltage.

For this reason, when the common mode voltage (the average voltage of the voltages at the first to third terminals 130 to 132) of the differential output signal of the frequency converter 101 decreases, the control current outputted by the control circuit 140 increases, thus increasing the voltage at any one of the first to third terminals 130 to 132. Meanwhile, when the common mode voltage (the average voltage of the voltages at the first to third terminals 130 to 132) of the differential output signal of the frequency converter 101 increases, the control current outputted by the control circuit 140 decreases, thus decreasing the voltage at any one of the first to third terminals 130 to 132. That is, the voltages at the first to third terminals 130 to 132 are coupled to each other in a negative feedback manner. For this reason, it is possible to prevent that the voltage at any one of the first to third terminals 130 to 132 is abnormally increased to be close to the power supply voltage Vcc. Similarly, it is also possible to prevent that the voltage is abnormally decreased to be close to the ground voltage.

According to the frequency converter 101 of the second embodiment, the control circuit 140 can prevent an abnormal change in the voltage at any one of the first to third terminals 130 to 132. In addition, since the constant current sources A11 to A13 that are used as the load circuit 150 have very large resistance values, it is possible to prevent the output signal from leaking to a power supply voltage supply line via the load circuit 150. As a result, it is possible to suppress attenuation of the output signal and thus to increase the conversion gain of the frequency converter 101.

Hereinafter, the reason why the frequency converter 101 of the second embodiment can diminish the effect of the flicker noise will be described.

Among the transistors included in the frequency converter 101 of the second embodiment, the transistor Q9 that is driven by the high-frequency signal and the transistors Q10 to Q12 that are driven by the three-phase local oscillation signal operate at a relatively high frequency, thus producing a small flicker noise. On the other hand, the transistors that serve as the constant current sources A11 to A13 and the control circuit 140 operate at a substantially zero frequency, thus producing a large flicker noise.

However, in the case of the constant current sources A11 to A13, it is possible to diminish the effect of the flicker noise from the same reason as described in connection with the constant current sources A1 and A2 of the first embodiment. Similarly, in the case of the transistors (the transistors Q13 to Q18) that serve as the control circuit 140 and the transistors that serve as the constant current source A14, it is possible to diminish the effect of the flicker noise from the same reason as described in connection with the transistors that serve as the control circuit 40 of the first embodiment.

In this way, according to the frequency converter 101 of the second embodiment, the control current generated on the basis of the difference between the predetermined reference voltage and the output voltage (common mode voltage) of the frequency converter 101 is added to the high-frequency current signal that is converted by the high-frequency input circuit 110. Accordingly, it is possible to increase the conversion gain and to diminish the effect of the flicker noise.

The frequency converter 101 of the second embodiment can be applied to a radio receiver. That is, the frequency converter 101 may be configured in such a manner to down-convert a radio signal (high-frequency signal) received through an antenna and to extract a signal component by means of a filter (while filtering out noise components), thereby receiving information from the signal component.

In radio communications, two signals that correspond to a real part and an imaginary part of a complex number are used. Here, the common mode voltage of the three-phase signal (i.e., the average voltage of the voltages of the three-phase signal) is assumed as a reference value (0V). In this case, it can be assumed that the three-phase signal is a set of two differential signals, and the degree of freedom becomes 2. In addition, a 2-dimensional vector representation such as a complex number representation (real part, imaginary part) can be obtained.

In the frequency converter 101 of the second embodiment, by using the three-phase local oscillation signal, it is possible to convert a radio reception signal to a three-phase baseband signal. In addition, as described above, since the frequency converter 101 can increase the conversion gain and diminish the effect of the flicker noise, it is possible to improve the signal reception characteristics of a radio receiver.

### Third Embodiment

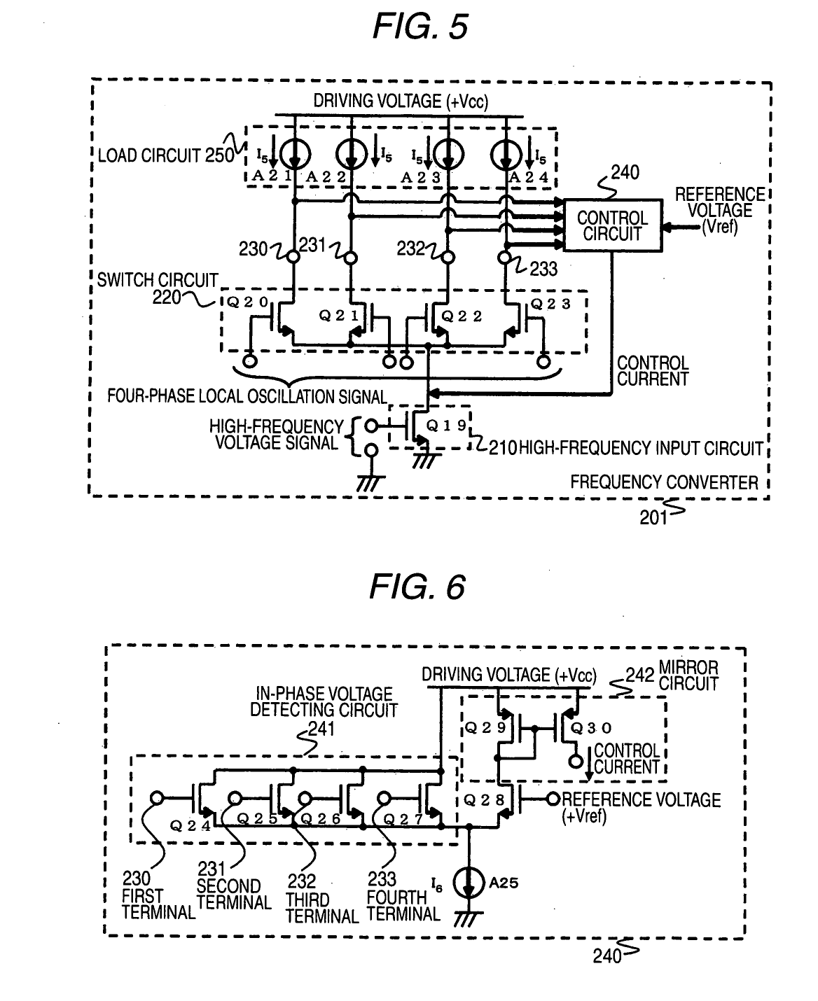

FIG. 5 is a block diagram showing the configuration of a frequency converter according to a third embodiment of the invention.

A frequency converter 201 of the third embodiment includes an n-channel MOSFET transistor Q19 in which a high-frequency voltage signal is inputted to a gate and a source is connected to the ground; n-channel MOSFET transistors Q20 to Q23 in which a four-phase local oscillation signal is inputted to respective gates, respective sources are connected to the drain of the transistor Q19, and respective drains are connected to any one of first to fourth terminals 230 to 233; a constant current source A21 that supplies a constant current I5 to the drain of the transistor Q20; a constant current source A22 that supplies a constant current I5 to the drain of the transistor Q21; a constant current source A23 that supplies a constant current I5 to the drain of the transistor Q22; a constant current source A24 that supplies a constant current I5 to the drain of the transistor Q23; and a control circuit 240 that generates a control current on the basis of a difference between a predetermined reference voltage Vref and the common mode voltage supplied from the first to fourth terminals 230 to 233 and supplies the control current to the drain of the transistor Q19.

The transistor Q19 serves as a high-frequency input circuit 210 that converts the high-frequency voltage signal as an input signal to the frequency converter 201 to a high-frequency current signal. The transistors Q20 to Q23 serve as a switch circuit 220 that distributes the high-frequency current signal to any one of the first to fourth terminals 230 to 233. The constant current sources A21 to A24 serve as a load circuit 250 that supplies a bias current to the high-frequency input circuit 210. The local oscillation signal inputted to the gate of the transistor Q20 and the local oscillation signal inputted to the gate of the transistor Q21 are 90 degrees out of phase with each other. In addition, the local oscillation signal inputted to the gate of the transistor Q22 is 180 degrees out of phase with the local oscillation signal inputted to the gate of the transistor Q20. In addition, the local oscillation signal inputted to the gate of the transistor Q23 is 180 degrees out of phase with the local oscillation signal inputted to the gate of the transistor Q21.

FIG. 6 is a block diagram showing the configuration of the control circuit 240 according to the third embodiment of the invention.

The control circuit 240 includes an n-channel MOSFET transistor Q24 in which a gate is connected to the first terminal 230 and a power supply voltage Vcc is supplied to a drain; an n-channel MOSFET transistor Q25 in which a gate is connected to the second terminal 231 and the power supply voltage Vcc is supplied to a drain; an n-channel MOSFET transistor Q26 in which a gate is connected to the third terminal 232 and the power supply voltage Vcc is supplied to a drain; an n-channel MOSFET transistor Q27 in which a gate is connected to the fourth terminal 233 and the power supply voltage Vcc is supplied to a drain; an n-channel MOSFET transistor Q28 in which the reference voltage Vref is supplied to a gate; a constant current source A25 that supplies a constant current I6 from the sources of the transistors Q24 to Q28 to the ground; a p-channel MOSFET transistor Q29 in which a gate and a drain are connected to the drain of the transistor Q28 and the power supply voltage Vcc is supplied to a source; and a p-channel MOSFET transistor Q30 in which a gate is connected to the gate of the transistor Q29 and to the drain of the transistor Q28 and the power supply voltage Vcc is supplied to a source.

The transistors Q24 to Q27 serve as an common mode voltage detecting circuit 241 that detects an common mode voltage of the voltages at the first to fourth terminals 230 to 233 that output the four-phase output signal. Here, the common mode voltage can be obtained by calculating the sum of the voltages at the first to fourth terminals 230 to 233. In addition, the transistors Q29 and Q30 serve as a mirror circuit 242. Therefore, the drain current of the transistor Q29, the drain current of the transistor Q28, and the drain current (the control current) of the transistor Q30 have the same current value.

Next, the operation of the frequency converter 201 of the third embodiment will be described.

First, the high-frequency voltage signal as the input signal to the frequency converter 201 is inputted to the gate of the transistor Q19. Since the gate of the transistor Q19 is supplied with the high-frequency voltage signal, the bias current flowing between the source and the drain of the transistor Q19 and supplied from the load circuit 250 fluctuates with the high-frequency voltage signal inputted to the gate of the transistor Q19. The bias current that fluctuates with the high-frequency voltage signal is referred to as the high-frequency current signal.

Next, the high-frequency current signal is outputted from any one of the first to third terminals 230 to 233 via the transistors Q20 to Q23 that serve as the switch circuit 220. The four-phase local oscillation signal is inputted to the gates of the transistors Q20 to Q23. For this reason, when any one of the transistors Q20 to Q23 is turned ON, the other three transistors are turned OFF. That is, the transistors Q20 to Q23 are alternately turned ON and OFF in a repeated manner.

In this case, the high-frequency current signal is distributed to any one of the first to fourth terminals 230 to 233 in accordance with a frequency of the local oscillation signal. For this reason, the first to fourth terminals 230 to 233 are supplied with a current (output signal) having a frequency different from the frequency of the high-frequency current signal (i.e., different from the frequency of the input high-frequency voltage signal).

Next, the operation of the control circuit 240 of the third embodiment will be described.

First, the voltages at the first to third terminals 130 to 132 of the frequency converter 201 are inputted to the control circuit 240. That is, the voltage at the first terminal 230 drives the transistor Q24; the voltage at the second terminal 231 drives the transistor Q25; the voltage at the third terminal 232 drives the transistor Q26; and the voltage at the fourth terminal 233 drives the transistor Q27. In addition, the reference voltage Vref drives the transistor Q28 disposed in parallel to the transistors Q24 to Q27.

Here, the sum of the drain currents of the transistors Q24 to Q28 is fixed at the current value I6 of the constant current source A25. For this reason, the drain currents of the transistors Q24 to Q28 are determined by a magnitude relation between the respective gate voltages. In addition, the gate voltage of the transistor Q28 is fixed at the reference voltage Vref. Therefore, the drain current of the transistor Q28 is determined by an average voltage of the gate voltage (the voltage at the first terminal 230) of the transistor Q24, the gate voltage (the voltage at the second terminal 231) of the transistor Q25, the gate voltage (the voltage at the third terminal 232) of the transistor Q26, and the gate voltage (the voltage at the fourth terminal 233) of the transistor Q27.

Since the first to third terminals 230 to 233 are configured to output a four-phase output signal, the average voltage of the voltages at the first to fourth terminals 230 to 233 is the common mode voltage of the four-phase output signal. When the common mode voltage of the four-phase output signal of the frequency converter 201 increases, the drain currents of the transistors Q24 to Q27 increase and the drain current of the transistor Q28 decreases. On the other hand, when the common mode voltage of the four-phase output signal of the frequency converter 201 decreases, the drain currents of the transistors Q24 to Q27 decrease and the drain current of the transistor Q28 increases.

The drain current of the transistor Q28 is the same as the drain current of the transistor Q29 that is serially connected to the transistor Q28. Since the gates of the transistors Q29 and Q30 are connected to each other and thus have the same voltage, the drain current of the transistor Q29 is the same as the drain current of the transistor Q30. The drain current of the transistor Q30 serves as the control current and is outputted from the control circuit 240.

The control current outputted from the control circuit 240 flows to the drain of the transistor Q19 that serves as the high-frequency input circuit 210. The gate voltage of the transistor Q19 is the high-frequency voltage signal and the drain current thereof is the high-frequency current signal. Therefore, the control current outputted by the control circuit 240 is added to the high-frequency current signal.

The control current added to the high-frequency current signal is outputted from any one of the first to fourth terminals 230 to 233 via the transistors Q20 to Q23 that serve as the switch circuit 220, in a manner similar to the high-frequency current signal. For this reason, the amount of the current outputted from any one of the first to fourth terminals 230 to 233 is increased by an amount corresponding to the control current added to the high-frequency current signal, thereby increasing the voltage.

For this reason, when the common mode voltage (the average voltage of the voltages at the first to fourth terminals 230 to 233) of the differential output signal of the frequency converter 201 decreases, the control current outputted by the control circuit 240 increases, thus increasing the voltage at any one of the first to fourth terminals 230 to 233. Meanwhile, when the common mode voltage (the average voltage of the voltages at the first to fourth terminals 230 to 233) of the differential output signal of the frequency converter 201 increases, the control current outputted by the control circuit 240 decreases, thus decreasing the voltage at any one of the first to fourth terminals 230 to 233. That is, the voltages at the first to fourth terminals 230 to 233 are coupled to each other in a negative feedback manner. For this reason, it is possible to prevent that the voltage at any one of the first to fourth terminals 230 to 233 is abnormally increased to be close to the power supply voltage Vcc. Similarly, it is also possible to prevent that the voltage is abnormally decreased to be close to the ground voltage.

According to the frequency converter 201 of the third embodiment, the control circuit 240 can prevent an abnormal change in the voltage at any one of the first to fourth terminals 230 to 233. Since the constant current sources A21 to A24 that are used as the load circuit 250 have very large resistance values, it is possible to prevent the output signal from leaking to a power supply line via the load circuit 250. As a result, it is possible to suppress attenuation of the output signal and thus to increase the conversion gain of the frequency converter 201.

Hereinafter, the reason why the frequency converter 201 of the third embodiment can diminish the effect of the flicker noise will be described.

Among the transistors included in the frequency converter 201 of the third embodiment, the transistor Q19 that is driven by the high-frequency signal and the transistors Q20 to Q23 that are driven by the four-phase local oscillation signal operate at a relatively high frequency, thus producing a small flicker noise. On the other hand, the transistors that serve as the constant current sources A21 to A24 and the control circuit 240 operate at a substantially zero frequency, thus producing a large flicker noise.

However, in the case of the constant current sources A21 to A24, it is possible to diminish the effect of the flicker noise from the same reason as described in connection with the constant current sources A1 and A2 of the first embodiment. Similarly, in the case of the transistors Q24 to Q30 that serve as the control circuit 240 and the transistors that serve as the constant current source A25, it is possible to diminish the effect of the flicker noise from the same reason as described in connection with the transistors that serve as the control circuit 40 of the first embodiment.

In this way, according to the frequency converter 201 of the third embodiment, the control current generated on the basis of the difference between the predetermined reference voltage and the output voltage (common mode voltage) of the frequency converter 201 is added to the high-frequency current signal that is converted by the high-frequency input circuit 210. Accordingly, it is possible to increase the conversion gain and to diminish the effect of the flicker noise.

The frequency converter 201 of the third embodiment can be applied to a radio receiver. That is, the frequency converter 201 may be configured in such a manner to down-convert a radio signal (high-frequency signal) received through an antenna and to extract a signal component by means of a filter (while filtering out noise components), thereby receiving information from the signal component.

In radio communications, two signals that correspond to a real part and an imaginary part of a complex number are used. In this case, assuming that the four-phase signal is a set of two differential signals, the degree of freedom becomes 2. In addition, a 2-dimensional vector representation such as a complex number representation (real part, imaginary part) can be obtained.

In the frequency converter 201 of the third embodiment, by using the four-phase local oscillation signal, it is possible to convert a radio reception signal to a four-phase baseband signal. In addition, as described above, since the frequency converter 201 can increase the conversion gain and diminish the effect of the flicker noise, it is possible to improve the signal reception characteristics of a radio receiver.

### Fourth Embodiment

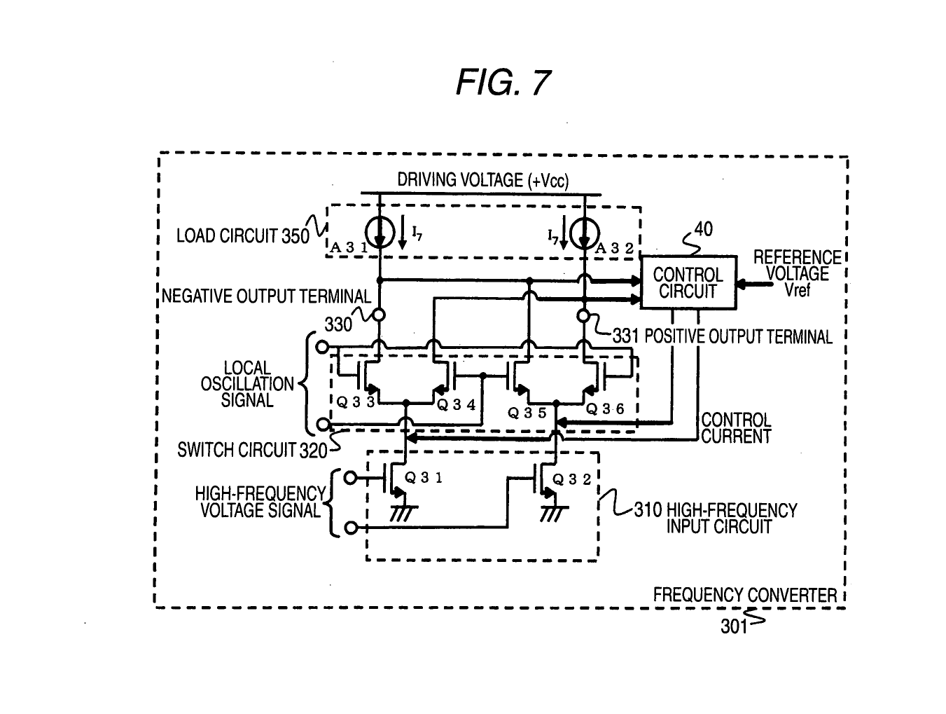

FIG. 7 is a block diagram showing the configuration of a frequency converter according to a fourth embodiment of the invention.

A frequency converter 301 of the fourth embodiment includes n-channel MOSFET transistors Q31 and Q32 in which a high-frequency voltage signal is differentially inputted to respective gates and respective sources are connected to the ground; n-channel MOSFET transistors Q33 and Q34 in which a local oscillation signal is differentially inputted to respective gates, respective sources are connected to the drain of the transistor Q31, and respective drains are connected to a negative output terminal 330 or a positive output terminal 331; n-channel MOSFET transistors Q35 and Q36 in which the local oscillation signal is differentially inputted to respective gates, respective sources are connected to the drain of the transistor Q32, and respective drains are connected to the negative output terminal 330 or the positive output terminal 331; a constant current source A31 that supplies a constant current I7 to the drains of the transistors Q33 and Q35; a constant current source A32 that supplies a constant current I7 to the drains of the transistors Q34 and Q36; and a control circuit 40 that generates a control current on the basis of a difference between a predetermined reference voltage Vref and the common mode voltage supplied from the negative output terminal 330 and the positive output terminal 331 and supplies the control current to the drains of the transistors Q31 and Q32.

The transistors Q31 and Q32 serve as a high-frequency input circuit 310 that converts the high-frequency voltage signal as an input signal to the frequency converter 301 to a high-frequency current signal. The high-frequency voltage signal inputted to the gate of the transistor Q31 and the high-frequency voltage signal inputted to the gate of the transistor Q32 are 180 degrees out of phase with each other.

The transistors Q33 to Q36 serve as a switch circuit 320 that distributes the high-frequency current signal to the negative output terminal 330 or the positive output terminal 331. The constant current sources A31 and A32 serve as a load circuit 350 that supplies a bias current to the high-frequency input circuit 310. The local oscillation signal inputted to the gates of the transistors Q33 and Q36 is 180 degrees out of phase with the local oscillation signal inputted to the gates of the transistors Q34 and Q35.

FIG. 2 is a block diagram showing the configuration of the control circuit 40 according to the fourth embodiment of the invention.

The control circuit 40 includes an n-channel MOSFET transistor Q4 in which a gate is connected to the negative output terminal 330 and a power supply voltage Vcc is supplied to a drain; an n-channel MOSFET transistor Q5 in which a gate is connected to the positive output terminal 331 and the power supply voltage Vcc is supplied to a drain; an n-channel MOSFET transistor Q6 in which the reference voltage Vref is supplied to a gate; a constant current source A3 that supplies a constant current I2 from the sources of the transistors Q4, Q5, and Q6 to the ground; a p-channel MOSFET transistor Q7 in which a gate and a drain are connected to the drain of the transistor Q6 and the power supply voltage Vcc is supplied to a source; and a p-channel MOSFET transistor Q8 in which a gate is connected to the gate of the transistor Q7 and to the drain of the transistor Q6 and the power supply voltage Vcc is supplied to a source. The drain of the transistor Q8 is connected to the drains of the transistors Q31 and Q32, and the drain current (control current) of the transistor Q8 is outputted to the drains of the transistors Q31 and Q32.

The transistors Q4 and Q5 serve as a common mode voltage detecting circuit 41 that detects a common mode voltage of the voltages at the negative output terminal 330 and the positive output terminal 331 that operate in a differential manner. Here, the common mode voltage can be obtained by calculating an average voltage of the voltages at the negative output terminal 330 and the positive output terminal 331. In addition, the transistors Q7 and Q8 serve as a mirror circuit 42. Therefore, the drain current of the transistor Q7, the drain current of the transistor Q6, and the drain current (the control current) of the transistor Q8 have the same current value.

Next, the operation of the frequency converter 301 of the fourth embodiment will be described.

First, the high-frequency voltage signal as the input signal to the frequency converter 301 is inputted to the gates of the transistors Q31 and Q32. Since the gates of the transistors Q31 and Q32 are supplied with the high-frequency voltage signal, the bias current flowing between the source and the drain of each of the transistors Q31 and Q32 and supplied from the load circuit 350 fluctuates with the high-frequency voltage signal. The bias current that fluctuates with the high-frequency voltage signal is referred to as the high-frequency current signal.

Next, the high-frequency current signal flowing to the transistor Q31 is outputted from the negative output terminal 330 or the positive output terminal 331 via the transistors Q33 and Q34 that serve as the switch circuit 320. the high-frequency current signal flowing to the transistor Q32 is outputted from the negative output terminal 330 or the positive output terminal 331 via the transistors Q35 and Q36 that serve as the switch circuit 320.

The local oscillation signal is differentially inputted to the transistors Q33 and Q34 and the transistors Q35 and Q36. For this reason, the transistors Q33 and Q36 set and the transistors Q34 and Q35 set are alternately turned ON and OFF in a repeated manner. The high-frequency current signal is outputted from the negative output terminal 330 or the positive output terminal 331 via any one of the transistors Q33 and Q36 set and the transistors Q34 and Q35 set.

In this case, the high-frequency current signal is distributed to the negative output terminal 330 and the positive output terminal 331 in accordance with a frequency of the local oscillation signal. For this reason, the negative output terminal 330 or the positive output terminal 331 is supplied with a current (output signal) having a frequency different from the frequency of the high-frequency current signal (i.e., different from the frequency of the input high-frequency voltage signal).

Next, the control circuit 40 supplies the control current to the drains of the transistors Q31 and Q32 on the basis of the difference between the predetermined reference voltage and the common mode voltage of the voltages of the negative output terminal 330 and the positive output terminal 331. The control current decreases as the common mode voltage of the voltages of the negative output terminal 330 and the positive output terminal 331 of the frequency converter 301 increases. Meanwhile, the control current increases as the common mode voltage of the voltages of the negative output terminal 330 and the positive output terminal 331 of the frequency converter 301 decreases.

Next, the control current outputted from the control circuit 40 flows to the drains of the transistors Q31 and Q32 that serve as the high-frequency input circuit 310. The gate voltages of the transistors Q31 and Q32 are the high-frequency voltage signal and the drain currents thereof are the high-frequency current signal. Therefore, the control current outputted by the control circuit 40 is added to the high-frequency current signal.

The control current added to the high-frequency current signal is outputted from the negative output terminal 330 or the positive output terminal 331 via the transistors Q33 to Q36 that serve as the switch circuit 320, in a manner similar to the high-frequency current signal. For this reason, the amount of the current outputted from the negative output terminal 330 or the positive output terminal 331 is increased by an amount corresponding to the control current added to the high-frequency current signal, thereby increasing the voltage.

For this reason, when the common mode voltage (the average voltage of the voltages at the negative output terminal 330 and the positive output terminal 331) of the differential output signal of the frequency converter 301 decreases, the control current outputted by the control circuit 40 increases, thus increasing the voltage at the negative output terminal 330 or the positive output terminal 331. Meanwhile, when the common mode voltage (the average voltage of the voltages at the negative output terminal 330 and the positive output terminal 331) of the differential output signal of the frequency converter 301 increases, the control current outputted by the control circuit 40 decreases, thus decreasing the voltage at the negative output terminal 330 or the positive output terminal 331. That is, the voltages at the negative output terminal 330 and the positive output terminal 331 are coupled to each other in a negative feedback manner. For this reason, it is possible to prevent that the voltage at the negative output terminal 330 or the positive output terminal 331 is abnormally increased to be close to the power supply voltage. Similarly, it is also possible to prevent that the voltage is abnormally decreased to be close to the ground voltage.

According to the frequency converter 301 of the fourth embodiment, the operation of the control circuit 40, can prevent an abnormal change in the voltage at the negative output terminal 330 or the positive output terminal 331. In addition, since the constant current sources A31 and A32 that are used as the load circuit 350 have very large resistance values, it is possible to prevent the output signal from leaking to a power supply line via the load circuit 350. As a result, it is possible to suppress attenuation of the output signal and thus to increase the conversion gain of the frequency converter 301.

Hereinafter, the reason why the frequency converter 301 of the fourth embodiment can diminish the effect of the flicker noise will be described.

Among the transistors included in the frequency converter 301 of the fourth embodiment, the transistors Q31 and Q32 that are driven by the high-frequency signal and the transistors Q33 to Q36 that are driven by the local oscillation signal operate at a relatively high frequency, thus producing a small flicker noise. On the other hand, the transistors that serve as the constant current sources A31 and A32 and the control circuit 40 operate at a substantially zero frequency, thus producing a large flicker noise.

However, in the case of the constant current sources A31 and A32, it is possible to diminish the effect of the flicker noise from the same reason as described in connection with the constant current sources A1 and A2 of the first embodiment. Similarly, in the case of the transistors that serve as the control circuit 40, it is possible to diminish the effect of the flicker noise from the same reason as described in connection with the transistors that serve as the control circuit 40 of the first embodiment.

In this way, according to the frequency converter 301 of the fourth embodiment, the control current generated on the basis of the difference between the predetermined reference voltage Vref and the output voltage (common mode voltage) of the frequency converter 1 is added to the high-frequency current signal that is converted by the high-frequency input circuit 310. Accordingly, it is possible to increase the conversion gain and to diminish the effect of the flicker noise.

### Fifth Embodiment

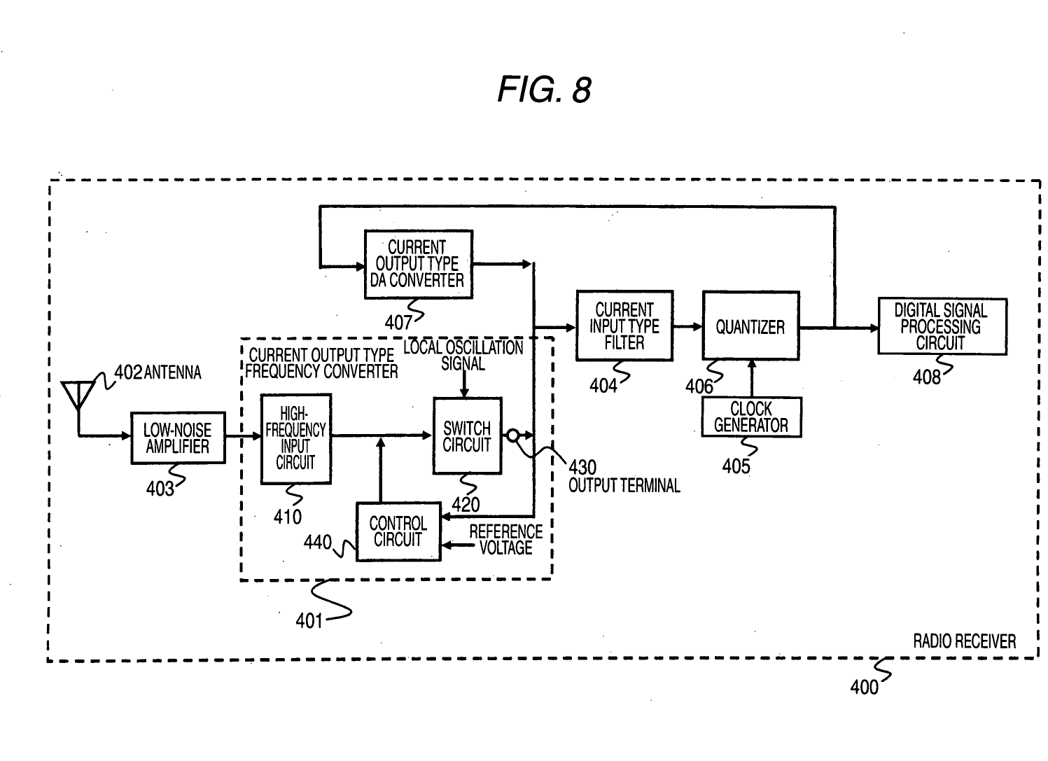

FIG. 8 is a block diagram showing the configuration of a radio receiver according to a fifth embodiment of the invention.

A radio receiver 400 of the fifth embodiment includes an antenna 402 that receives a radio signal modulated for information transmission; a low-noise amplifier 403 that amplifies the radio signal received through the antenna 402 and outputs a high-frequency voltage signal; a high-frequency input circuit 410 that converts the high-frequency voltage signal to a high-frequency current signal; a switch circuit 420 that selectively supplies the high-frequency current signal to an output terminal 430 in accordance with a local oscillation signal and outputs an analog current signal; a control circuit 440 that adds a control current that is generated on the basis of a difference between a predetermined reference voltage and the voltage at the output terminal 430 of the switch circuit 420 to the high-frequency current signal; a current input type filter 404 that filters out noise components from the analog current signal and outputs an analog voltage signal; a clock generator 405 that generates a clock signal having a frequency higher than that of the analog voltage signal; a quantizer 406 that operates in synchronization with the clock signal and quantizes the analog voltage signal so as to convert the analog voltage signal to a digital voltage signal; a digital signal processing circuit 408 that performs digital signal processing using the digital voltage signal; and a current output type DA (Digital-to-Analog) converter circuit 407 that adds an analog feedback current corresponding to the digital voltage signal to the analog current signal.

The high-frequency input circuit 410, the switch circuit 420, and the control circuit 440 serve as a current output type frequency converter 401 that converts the frequency of the input high-frequency voltage signal and outputs the analog current signal. The current input type filter 403, the quantizer 406, and the current output type DA converter 407 serve as a so-called delta-sigma modulator that converts the input analog current signal to a bit sequence of the order of one to several bits.

Next, the operation of the radio receiver 400 of the fifth embodiment will be described.

First, the antenna 402 receives a radio signal that is modulated for information transmission. The low-noise amplifier 403 amplifies the radio signal received through the antenna 402 to a predetermined level and outputs the amplified radio signal to the current output type frequency converter 401 as a high-frequency voltage signal.

The frequency converter of the first to fourth embodiments may be used as the current output type frequency converter 401. The high-frequency input circuit 410 converts the high-frequency voltage signal received from the low-noise amplifier 403 to a high-frequency current signal. The switch circuit 420 distributes the high-frequency current signal received from the high-frequency input circuit 410 to two or more output terminals 430 of the current output type frequency converter 401 in accordance with a local oscillation signal. The current supplied from the switch circuit 420 to the output terminals 430 serves as the output (analog current signal) of the current output type frequency converter 401. The control circuit 440 adds the control current to the high-frequency current on the basis of the voltage at the output terminals 430 of the current output type frequency converter 401. The current output type frequency converter 401 has a high conversion gain and can diminish the effect of the flicker noise.

Next, the current input type filter 404 receives the analog current signal from the current output type frequency converter 401 and outputs the analog current signal to the quantizer 406 while filtering out noise components from the analog current signal. The current input type filter 404 is a so-called continuous-time filter and filters out noises from the signal that is frequency-converted by the current output type frequency converter 401 in a repeated manner. In addition, the current input type filter 404 has a function of increasing a gain at a target frequency of the loop that is configured by the current input type filter 404, the quantizer 406, and the current output type DA converter 407.

Next, the quantizer 406 quantizes the analog voltage signal received from the current input type filter 404 on the basis of the clock signal generated by the clock generator 405. Here, the frequency of the clock signal generated by the clock generator 405 is higher than the maximum frequency of the analog voltage signal (in the current state, the frequency is about 10 to 100 times the maximum frequency of the analog voltage signal). For this reason, the quantizer 406 performs high-order oversampling. That is, the quantizer 406 converts the analog voltage signal to a digital voltage signal of one to several bits and outputs the digital voltage signal to the digital signal processing unit 408 and the current output type DA converter 407.

Next, the digital signal processing unit 408 receives the digital voltage signal from the quantizer 406 and converts the digital voltage signal to original digital data (information), thereby performing data processing on the digital data.

The current output type DA converter 407 receives the digital voltage signal from the quantizer 406 and adds a feedback current corresponding to the digital voltage signal to the analog current signal. For example, if the digital voltage signal (the signal outputted by the quantizer 406) has a bit width of 2 bit, the value which the digital voltage signal can have is “0,” “1,” “2,” or “3”. In this case, the current output type DA converter 407 uses, as the current value of the feedback current, a value obtained by multiplying the value of the digital voltage signal with a constant current value.

In this way, according to the radio receiver 400 of the fifth embodiment, even when the amplitude of the input signal is low, the delta-sigma modulator can perform AD conversion at high resolution. In addition, since the control current based on the difference between the predetermined reference voltage and the output voltage (common mode voltage) of the current input type frequency converter 401 is added to the high-frequency current signal, it is possible to increase the conversion gain and to diminish the effect of the flicker noise. Accordingly, it is possible to improve the signal reception characteristics of the radio receiver 400.

The bias current outputted from the current output type DA converter 407 flows to the current output type frequency converter 401. For this reason, the current output type DA converter 407 functions as a load circuit of the current output type frequency converter 401. That is, the current output type frequency converter 401 and the current output type DA converter 407 can use the bias current in common, thus decreasing power consumption.

In the radio receiver 400 of the above embodiment, it has been described that the quantizer 406 performs high-order oversampling, and the current input type filter 404, the quantizer 406, and the current output type DA converter 407 serve as the delta-sigma modulator.

Besides, a configuration is also conceivable in which the radio receiver 400 does not have the current output type DA converter 407, and the feedback current corresponding to the digital voltage signal outputted by the quantizer 406 is not added to the analog current signal as the input signal to the current input type filter 404.

According to such a configuration, the control current based on the difference between the predetermined reference voltage and the output voltage (common mode voltage) of the current output type frequency converter 401 is added to the high-frequency current signal. Therefore, it is possible to increase the conversion gain of the current output type frequency converter 401 of the radio receiver 400 and to diminish the effect of the flicker noise. Accordingly, it is possible to improve the signal reception characteristics of the radio receiver 400 with a simple and easy configuration.

According to the above-mentioned embodiments, it becomes possible to provide a frequency converter and a radio receiver using the same, in which a current corresponding to the voltage at an output terminal of the frequency converter is added to the current flowing between an input circuit and a switch circuit, thereby increasing a conversion gain and diminishing the effect of the flicker noise.

The present invention is not limited to the embodiments in their entirety, but in the implementation stage, the present invention may be embodied in such a manner that components thereof are modified within the scope not departing from the gist of the present invention. In addition, various inventions can be made by properly combining a plurality of components disclosed in the embodiments. For example, several components may be eliminated from the entire components disclosed in the embodiments. Furthermore, components in different embodiments may properly be combined.

What is claimed is:

1. A frequency converter, comprising:
an input circuit converting a voltage signal to a current signal;
a first and second output terminals both outputting a differential output signal based on the converted voltage signal;
a load circuit supplying a constant current to an input circuit;
a first switch circuit provided between the load circuit and the input circuit and configured to output the current signal from the first output terminal in accordance with a switching that is made in accordance with a first oscillation signal;
a second switch circuit provided between the load circuit and the input circuit and configured to output the current signal from the second output terminal in accordance with a switching that is made in accordance with a second oscillation signal being 180 degrees out of phase with the first oscillation signal;
a control circuit generating a control current based on a predetermined reference voltage and an average voltage of the voltages at the first and second output terminals and adding the control current to the current signal of the input circuit.

2. The frequency converter according to claim 1, wherein the control circuit comprises:
a first transistor and a second transistor both driven by the voltages supplied from the first output terminal and the second output terminal, respectively;
a third transistor driven by the reference voltage; and
a constant current source connected to the first to third transistors, the control circuit adding a current equal to an amount of a current flowing in the third transistor to the corresponding current signal.

3. A frequency converter, comprising:
an input circuit converting a voltage signal to a current signal;
a first output terminal, a second output terminal; and
a third output terminal, the first to third output terminals outputting a three-phase output signal based on the converted voltage signal;
a load circuit supplying a constant current to the input circuit;
a first switch circuit provided between the load circuit and the input circuit and configured to output the current signal from the first output terminal in accordance with a switching made in accordance with a first oscillation signal;
a second switch circuit provided between the load circuit and the input circuit and configured to output the current signal from the second output terminal in accordance with a switching made in accordance with a second oscillation signal being 120 degrees out of phase with the first oscillation signal;
a third switch circuit provided between the load circuit and the input circuit and configured to output the current signal from the third output terminal in accordance with a switching made in accordance with a third oscillation signal being 120 degrees out of phase with the first and second oscillation signals, respectively; and
a control circuit generating a control current based on a predetermined reference voltage and an average voltage of the voltages at the first to third output terminals and adding the control current to the corresponding current signal.

4. The frequency converter according to claim 3, wherein the control circuit comprises:
first to third transistors driven by the voltages supplied from the first to third output terminals, respectively;
a fourth transistor driven by the reference voltage; and
a constant current source connected to the first to fourth transistors, the control circuit adding a current equal to an amount of a current flowing in the fourth transistor to the corresponding current signal.

5. A frequency converter, comprising:
an input circuit converting a voltage signal to a current signal;
a first output terminal, a second output terminal, a third output terminal, and a fourth output terminal, the first to fourth output terminal outputting a four-phase output signal based on the converted voltage signal;
a load circuit supplying a constant current to the input circuit;
a first switch circuit provided between the load circuit and the input circuit and configured to output the current signal form the first output terminal in accordance with a switching made in accordance with a first oscillation signal;
a second switch circuit provide between the load circuit and the input circuit and configured to output the current signal from the second output terminal in accordance with a switching made a second oscillation signal being 90 degrees out of phase with the first oscillation signal;
a third switch circuit provided between the load circuit and the input circuit and configured to output the current signal from the third output terminal in accordance with a switching made in accordance with a third oscillation signal being 180 degrees out of phase with the first oscillation signal;
a fourth switch circuit provided between the load circuit and the input circuit and configured to output the current signal from the fourth output terminal in accordance with a switching made in accordance with a third oscillation signal being 180 degrees out of phase with the second oscillation signal; and
a control circuit generating a control current based on a predetermined reference voltage and an average voltage of the voltages at the first to fourth output terminals and adding the control current to the corresponding current signal.

6. The frequency converter according to claim 5, wherein the control circuit comprises:
first to fourth transistors driven by the voltages supplied from the first to fourth output terminals, respectively;
a fifth transistor driven by the reference voltage; and
a constant current source connected to the first to fifth transistors, the control circuit adding a current equal to an amount of the current flowing to the fifth transistor to the corresponding current signal.

7. A frequency converter, comprising:
a first input circuit converting a first voltage signal to a first current signal;
a second input circuit converting the first voltage signal to a second current signal;
a first load circuit supplying a constant current to a first input circuit;
a second load circuit supplying a constant current to a second input circuit;
a first and second output terminals both outputting a differential output signal based on the converted voltage signal;
a first switch circuit provided between the first load circuit and the first input circuit and configured to output the first current signal from the first output terminal in accordance with a switching made in accordance with a first oscillation signal;
a second switch circuit provided between the second load circuit and the second input circuit and configured to output the second current signal from the second output terminal in accordance with a switching made in accordance with the first oscillation signal;
a third switch circuit provided between the first load circuit and the second input circuit and configured to output the second current signal from the first output terminal in accordance with a switching made in accordance with a second oscillation signal being 180 degrees out of phase with the first oscillation signal;
a fourth switch circuit provided between the second load circuit and the first input circuit and configured to output the first current signal from the second output terminal in accordance with a switching made in accordance with the second oscillation signal; and
a control circuit generating a control current based on a predetermined reference voltage and an average voltage of the voltages at the first and second output terminals and adding the control current to the corresponding first and second current signals.

8. The frequency converter according to claim 7, wherein the control circuit comprises:
first and second transistors both driven by the voltages supplied from the first and second output terminals, respectively;
a third transistor driven by the reference voltage; and
a constant current source connected to the first to third transistors, the control circuit adding a current equal to an amount of a current flowing in the third transistor to the corresponding first current signal and the corresponding second current signal.

9. A radio receiver, comprising:
an antenna that receives a radio signal;
an amplifier that amplifies the radio signal and outputs a high-frequency voltage signal; a frequency converter, comprising:
an input circuit converting a voltage signal to a current signal;
a first and second output terminals both outputting a differential output signal based on the converted voltage signal;
a load circuit supplying a constant current to the input circuit;
a first switch circuit provided between the load circuit and the input circuit and configured to output the current signal form the first output terminal in accordance with a switching made in accordance with a first oscillation signal;
a second switch circuit provide between the load circuit and the input circuit and configured to output the current signal from an second output terminal in accordance with a switching made a second oscillation signal being 90 degrees out of phase with the first oscillation signal;
a third switch circuit provided between the load circuit and the input circuit and configured to output the corresponding current signal from a third output terminal in accordance with a switching made in accordance with a third oscillation signal being 180 degrees out of phase with the first oscillation signal;
a fourth switch circuit provided between the load circuit and the input circuit and configured to output the corresponding current signal from a fourth output terminal in accordance with a switching made in accordance with a third oscillation signal being 180 degrees out of phase with the second oscillation signal; and
a control circuit generating a control current based on a predetermined reference voltage and an average voltage of the voltages at the first to fourth output terminals and adding the control current to the corresponding current signal;
a filter that filters out noise components from an analog current signal outputted from the frequency converter and outputs an analog voltage signal;
a quantizer that quantizes the analog voltage signal outputted from the filter and converts the analog voltage signal to a digital signal; and
a digital signal processing unit that processes the digital signal outputted from the quantizer.
